(19) United States
(12) Patent Application Publication
(10) Pub. No.: US 2024/0266805 A1
(43) Pub. Date: Aug. 8, 2024

(54) SEMICONDUCTOR COMPONENT

(71) Applicant: TRUMPF Photonic Components GmbH, Ulm (DE)

(72) Inventors: Andrea Ott, Beimerstetten (DE); Sven Bader, Neu-Ulm (DE)

(21) Appl. No.: 18/638,767

(22) Filed: Apr. 18, 2024

Related U.S. Application Data
(63) Continuation of application No. PCT/EP2022/078422, filed on Oct. 12, 2022.

(30) Foreign Application Priority Data
Oct. 21, 2021 (DE) 10 2021 127 409.5

(51) Int. Cl. H01S 5/183; H01S 5/042

(52) U.S. Cl. CPC H01S 5/18355; H01S 5/0421

(57) ABSTRACT

A semiconductor component includes a main body, which includes at least one mesa body. The mesa body includes an emission region for emitting light, and an electrical contact for feeding electrical energy into an active portion of the emission region. The electrical contact includes a stress element extending up to the emission region and attached to a surface of the main body, and configured to generate a material stress in the main body. The main body further includes a polarization grating arranged on a surface of the mesa body and configured to interact with the emission region. A grating alignment of the polarization grating includes an angle of 0°, 45° or 90° with respect to a direction of a predominant material stress or a longitudinal extent of the stress element, such that the material stress and the grating alignment have an effect on a property of the emitted light.

### CROSS REFERENCE TO RELATED APPLICATIONS

This application is a continuation of International Application No. PCT/EP2022/078422 (WO 2023/066761 A1), filed on Oct. 12, 2022, and claims benefit to German Patent Application No. DE 10 2021 127 409.5, filed on Oct. 21, 2021. The aforementioned applications are hereby incorporated by reference herein.

### FIELD

Embodiments of the present invention relate to a semiconductor component for emitting light, and to a method for producing a material stress within a main body of a semiconductor component.

### BACKGROUND

Strong electric fields are formed on account of the small structural size, and these have an effect on the refractive index of the material forming the basis of the semiconductor component. By way of example, this effect is problematic in the case of VCSELs (vertical-cavity surface-emitting lasers), according to which the polarization direction of the emitted light is not permanently stationary under all operating conditions.

Light-emitting semiconductor components such as VCSELs, which may also be equipped with an integrated photodiode for example and which are used in sensor applications in particular, however require a polarization of the emitted light that is stable in respect of the polarization direction and preferably linear.

### SUMMARY

Embodiments of the present invention provide a semiconductor component for emitting light. The semiconductor component includes a main body. The main body includes at least one mesa body. The mesa body includes an emission region for the light. The emission region includes a first mirror portion, a second mirror portion, and an active portion arranged between the first mirror portion and the second mirror portion and serving to produce the light. The mesa body further includes an electrical contact for feeding electrical energy into the active portion. The electrical contact includes at least one stress element extending up to the emission region. The stress element is attached to a surface of the main body and configured to generate, in the main body, a material stress. The main body further includes a polarization grating arranged on a surface of the mesa body and configured to interact with the emission region. A grating alignment of the polarization grating includes an angle of 0°, 45° or 90° with respect to a direction of a predominant material stress or a longitudinal extent of the stress element, such that the material stress and the grating alignment have an effect on a property of the emitted light.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a semiconductor component for emitting light having a main body and two mesa bodies having respective electrical contacts having stress elements with different alignment and a polarization grating on a mesa body, according to some embodiments;

FIG. 2 shows a semiconductor component for emitting light having a main body and two mesa bodies having respective electrical contacts having stress elements with different alignment and polarization gratings, wherein a top layer is reduced in an emission region, according to some embodiments;

FIG. 3 shows a semiconductor component for emitting light having a main body and two mesa bodies having respective electrical contacts having stress elements with different alignment and polarization gratings, wherein the polarization gratings are aligned orthogonally with respect to one another, according to some embodiments;

FIG. 4 shows a semiconductor component for emitting light, having a main body and three mesa bodies, according to some embodiments; and

FIG. 5 shows an array of mesa bodies with different polarization properties, according to some embodiments.

### DETAILED DESCRIPTION

Embodiments of the present invention provide a semiconductor component for emitting light, said semiconductor component comprising a main body that comprises a mesa body having an emission region for the light, which is assigned a first mirror portion, a second mirror portion and an active portion arranged between the two mirror portions and serving to produce the light, and said semiconductor component comprising electrical contacts for feeding electrical energy into the active portion, with at least one, preferably mechanical stress element being attached to a surface of the main body and generating, in the main body, an additional material stress in the preferred direction which has an effect on properties, such as a polarization extinction ratio, of the emitted light.

Additionally, a polarization grating interacts together with an emission region and is arranged on the surface of the mesa body, a grating alignment of the polarization grating including an angle of 0°, 45° and/or 90° with a crystal axis of the semiconductor device and/or with a direction of a predominant material stress and/or a longitudinal extent of a stress element. The grating alignment is determined by the longitudinal extent of the grating ribs.

The main body and the mesa body contain at least partly crystalline semiconductor material, through which the light can propagate in order to be able to emerge from the emission region to the outside. The crystalline semiconductor material has birefringent properties. The emergent light is essentially polarized in two mutually independent, preferably orthogonal directions. The ratio of the two intensities of the polarization directions is referred to as polarization extinction ratio (PER).

The material stress additionally generated by the stress element may have in terms of the stress intensity a reducing gradual profile in the direction of the interior of the main body starting from the stress element. Further, a stress element preferably generates a material stress which predominantly acts in one direction within the material of the main body.

At least one of the electrical contacts comprises a stress element, the stress element being able to be a metallic coating on the mesa body in particular. In this context, the stress element may be electrically conductive and have an electrical connection to the electrical contact. The stress element may be an integral constituent part of the electrical contact. A compact structure of the semiconductor component can be ensured by way of the functional connection between the stress element and the electrical contact.

Properties of the emergent light can be changed by the material stress and the polarization grating, with the polarization extinction ratio in particular being changed. In particular, the polarization extinction ratio can be changed by virtue of changing birefringent properties of the crystalline material that forms the basis of the main body. Depending on the alignment of the material stress and the polarization grating in relation to the crystal axes, for example in the (110) or (1-10) direction according to Miller indices, it is possible to cause a change in the intensity of the two polarization directions. In particular, the intensity of a first polarization direction is increased and the intensity of a second polarization direction is reduced at the same time.

In particular, the semiconductor component may be a surface emitter (VCSEL—Vertical-Cavity Surface-Emitting Laser). The light may in particular, be coherent laser light which emerges divergently from the emission region. The light may be polarized, collimated or focused by optical elements, which preferably include diffractive, refractive and/or photonic meta-material. In particular, the semiconductor component can be a combination of at least one VCSEL with at least one integrated photodiode.

It is also advantageous to provide at least two mesa bodies, wherein each mesa body can be assigned a stress element and a respective emission region can be assigned a polarization grating. It is conceivable in this case to provide only one emission region with a polarization grating and to leave the other emission region without a polarization grating. If the emission region and/or the material stress of different mesa bodies which is produced by stress elements are designed differently, then differently polarized light is emitted accordingly.

As an alternative, each emission region can be provided with a polarization grating. In this case, the polarization gratings may be aligned identically or differently. If the polarization gratings are aligned differently, it is conceivable to align adjacent polarization gratings orthogonally or at a 45° angle to one another. It is also conceivable to choose an angle other than 90° or 45°.

In a development, provision can be made for at least two separate stress elements to be attached to the main body and for each to generate a predominant material stress in a different direction, the directions preferably extending at an angle of 0°, 45° and/or 90° with respect to one another and/or with respect to the crystal axes of the semiconductor device. In particular, it is conceivable to arrange exactly two mutually perpendicular stress elements on the surface of the main body, said stress elements generating two substantially perpendicular material stresses. A semiconductor component can preferably comprise two mesa bodies, with each mesa body being assigned one stress element in particular. As a result of the many possibilities for arranging the advantageous stress elements, it is possible to form the material stress within the main body in virtually any desired manner.

By preference, provision may be made for the top layer forming the surface and preferably designed as an epitaxially grown sealing layer to be thinner in the region of a first emission region than in the region of a second emission region. In this case, the height of the top layer can be reduced in the region of the emission region by an etching step. Etching of the sealing layer results in a change in the preferred polarization direction.

In particular, provision can be made for a longitudinal extent of the stress element to include an angle of 0°, 45° and/or 90° with a crystal axis of the main body. Furthermore, the grating alignment of the polarization grating can include an angle of 0°, 45° and/or 90° with a crystal axis of the main body. The crystal axis is specified by the crystal structure of the crystal underlying the material of the semiconductor component. By way of example, the crystal axes can be specified by mutually independent spatial directions within the crystal. By preference, the crystal axes are specified by directions within the crystal in which the periodic repetition of the crystal structure has the shortest distances. These crystal directions are also referred to as principal crystal directions. In the case of gallium arsenide, these may be in the (110) or (1-10) direction.

Furthermore, it is possible to form an array which has a semiconductor component which has a plurality of adjacent mesa rows, each having a plurality of mesa bodies which are preferably arranged along an imaginary line. In this case, a device may comprise the array having the semiconductor components.

By preference, a first mesa row can emit light with different polarization properties to a second mesa row. The light of the different mesa rows has different polarization extinction ratios, wherein in particular the light of adjacent mesa rows (98) have different polarization extinction ratios and different manifestations of elliptical polarization to one another.

It is to be understood that the features specified above and the features yet to be explained below can be used not only in the respectively specified combination but also in other combinations.

Each of the figures depicts semiconductor components 10 which are embodied to emit light. The light can be coherent light such as laser light. In this case, wavelengths ranging from 550 nm to 1500 nm, in particular, are possible, with wavelengths between 700 nm and 1000 nm, in particular, being emitted. The light may in particular, be coherent laser light which emerges divergently from the emission region. The light may be polarized, collimated or focused by optical elements, which preferably include diffractive, refractive and/or photonic meta-material.

The semiconductor component 10 comprises a main body 14, which has at least one mesa body 16 with an emission region 18 for the light. Both the main body 14 and the mesa body 16 may comprise crystalline semiconductor material at least in part, the latter containing indium, gallium, arsenic and/or phosphorus. The emission region 18 is a surface location from where the light emerges from the semiconductor component 10 into the surroundings. The environment may include an optical device for refraction and diffraction and may be an air-filled or vacuum-filled space. The mesa body 16 may be tower-shaped and, in particular, have a circular cylindrical form, wherein the radius of the diameter can be approximately ≤30 μm, with a diameter of ≤20 μm also being possible. Alternatively, the diameter may also be greater than 30 μm.

A first mirror portion, a second mirror portion and an active portion arranged between the two mirror portions and serving to produce the light (12) are assigned to the mesa body 16. The mirror sections and the active section are not illustrated in the figures. The material stress can also affect the mirror sections and the active section. They may be wholly or partially encompassed by the mesa body 16. In particular, the mirror portions and the active portion are arranged in the main body 14.

The crystalline semiconductor material of the main body 14 and/or mesa body 16 has birefringent properties, and so the light that propagates through the semiconductor material is polarized in two different directions. The emergent light is essentially polarized in two preferably mutually orthogonal polarization directions 171, 172. The two polarization directions 171, 172 generate an elliptical polarization post emergence as a result of the superposition of their electromagnetic fields, with the longitudinal extent of the resultant ellipse being directed in the more intensive polarization direction 171, 172. However, a linear polarization or an elliptical polarization of the emitted light is preferably sought after.

The ratio of the intensities of the two polarization directions 171, 172 is referred to as polarization extinction ratio. Material stresses in the crystalline semiconductor material and/or a polarization grating through which the emitted light passes can influence the polarization extinction ratio.

Light-emitting semiconductor components 10 such as VCSELs, which are used in sensor applications in particular, require in particular a time-stationary polarization extinction ratio of the emitted light 12. This can be achieved by virtue of the intensities of the polarization directions 171, 172 being stable over time.

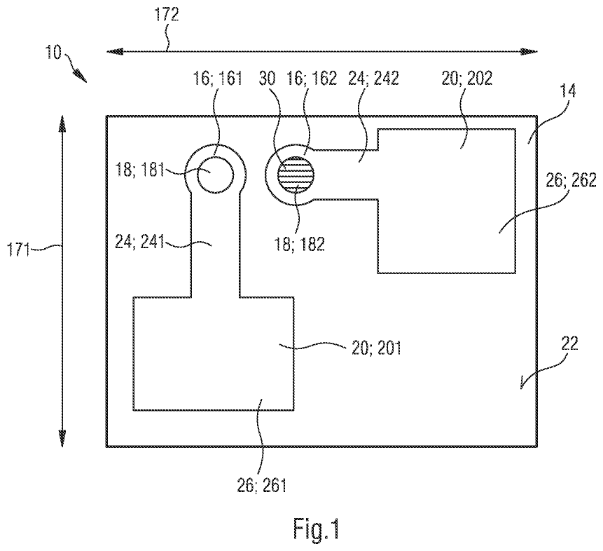

FIG. 1 depicts a surface 22 of an exemplary semiconductor component 10, which has a first and a second mesa body 161, 162 on preferably a common main body 14. Electrical contacts 20; 201, 202, which serve to feed electrical energy into the active portion of the mesa bodies 161, 162, are applied to the surface 22.

Each electrical contact 20; 201, 202 has a stress element 24; 241, 242 and a connection portion 26; 261, 262 provided for electrically connecting the semiconductor component 10 to peripheral devices not depicted here. Merely one contact 20; 201, 202 may be equipped with a stress element 24; 241, 242.

The stress element 24; 241, 242 is of a stripe-type design, with the stress element 24; 241, 242 preferably extending between the respective emission region 181, 182 and the respectively assigned connection portion 26; 261, 262.

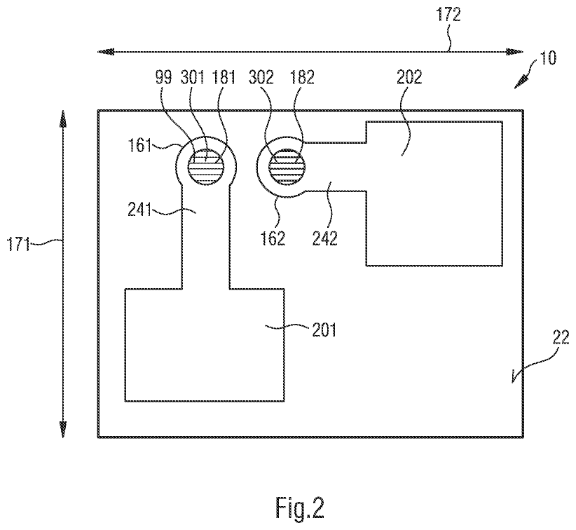

In the exemplary embodiment of FIG. 2, the first stripe-type stress element 241 extends along a first crystal axis 271 and the second stripe-type of stress element 242 extends along a second crystal axis 272. By way of example, the crystal axes 271, 272 may be represented by the Miller indices (011) and (01-1). Other Miller indices are also conceivable. The two stress elements 24; 241, 242 are essentially arranged perpendicular to one another in the plane of the surface 22.

A force predominantly directed along the direction of longitudinal extent of the stress element 24; 241, 242 acts on the material volume as a result of a stripe-type stress element 24; 241, 242, said force being expressed in a material stress 25 within the material of the main body 14. When the stress element 24; 241, 242 is arranged in the mesa body 16, then it also generates a material stress in the mesa body 16. The stress element 24; 241, 242 generates a material stress, which has an effect on the birefringent properties of the crystalline semiconductor material. The polarization extinction ratio is influenced as a result. In particular, the intensity of a first polarization direction 171 is increased and the intensity of a second polarization direction 172 is reduced at the same time, or vice versa.

In the case of stripe-type of stress elements 24; 241, 242, the material stress is distinguished by a magnitude directed predominantly along the longitudinal extent of the stress element 24; 241, 242. In this case, the material stress is strongest in the region of the surface 22 in particular and decreases with increasing depth perpendicular to the surface 22.

Additionally, a polarization grating 30; 301, 302 can be arranged on the respective emission region 18; 181, 182. The polarization grating 30; 301, 302 is preferably arranged on the surface 22 of the mesa body 16; 161, 162. Alternatively, the polarization grating 30; 301, 302 may also be arranged within the semiconductor component 10.

According to FIG. 1, the semiconductor component 10 has two mesa bodies 16; 161, 162. Both mesa bodies 161, 162 are assigned stress elements 24; 241, 242, wherein the first stress element 241 is offset by 90° with respect to the second stress element 242. As an example, only the second mesa body 162 is equipped with a polarization grating 30. The polarization grating 30 has a grating alignment that includes an angle of 0° with the second stress element 242. The first mesa body 161 is designed by way of example without polarization gratings 30.

Combining the mesa bodies 16 which are equipped with different polarization gratings 30 makes it possible to vary the polarization angle of the resulting polarization.

The grating alignment is determined by the angle between the longitudinal extent of the grating ribs of the polarization grating 30; 301, 302 and the longitudinal extent of the respectively assigned stress element 24; 241, 242, and hence with a direction of a predominant material stress. One stress element 241, 242 in each case extends from the respective mesa body 161, 162 to the electrical contacts 20; 201, 202.

As an alternative to the embodiment of FIG. 2, it is possible to provide both emission regions 181, 182 of the semiconductor component 10 with a polarization grating 16. The grating alignment of the polarization gratings 301, 302 of the respective emission region 181, 182 include in particular an angle of 0°, 45° and/or 90° with the direction of a predominant respective material stress and/or a longitudinal extent of the respective stress element 241, 242.

FIG. 2 illustrates a semiconductor component 10 which has electrical contacts 20; 201, 202 according to FIG. 1. Each emission region 181, 182 is equipped by way of example with a polarization grating 301, 302. The first polarization grating 201 is offset by 90° with respect to the longitudinal extent of the first stress element 241 and the second polarization grating 242 is offset by 0° relative to the longitudinal extent of the second stress element 242.

In addition to the first polarization grating 301, a top layer 99 forming the surface 22 of the semiconductor component 10 is thinner in the region of the first emission region 181 than in the region of the second emission region 182. Reducing the thickness of the top layer 99 strengthens one of the two polarization directions 171, 172 compared to the other polarization directions 171, 172. As a result, the thickness of the top layer 99 can interact with the polarization grating 30 applied to the respective emission region 18.

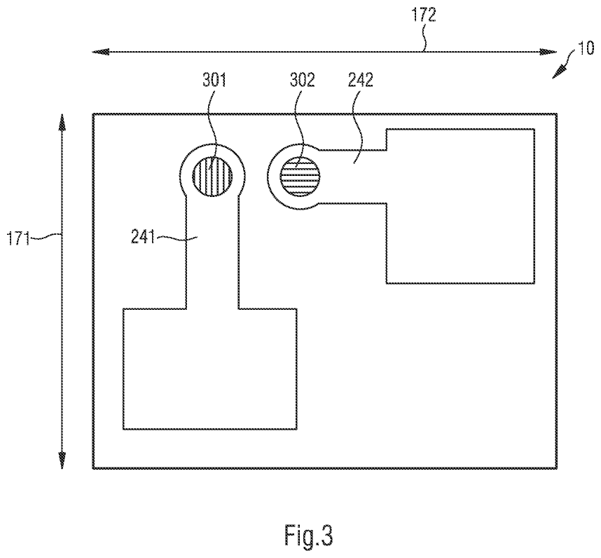

In FIG. 3, a first mesa body 161 and a second mesa body 162 are formed on the semiconductor component 10, wherein the stress elements 241, 242 have an identical configuration to FIGS. 1 and 2. However, the polarization gratings 301, 302 are aligned differently, such that the grating alignments include an angle of 90°, for example.

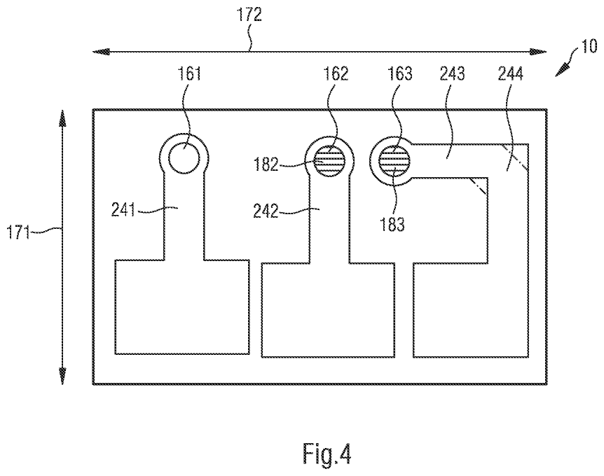

In FIG. 4, three mesa bodies 161, 162, 163 are encompassed by a semiconductor component, wherein the stress elements 241, 242 assigned to the first and the second mesa body 161, 162 are aligned parallel to one another and aligned at a 90° angle with respect to the third stress element 243. In an alternative, an alternative third stress element 244 is aligned at a 45° angle.

The polarization gratings 30 can be selected as desired, irrespective of the alignment of the stress elements 241, 242, 243, 244. By way of example, the polarization gratings in FIG. 4 are aligned on the second and third emission region 182, 183 at a 90° angle with respect to the first and second stress element 241. The first emission region 181 does not have a polarization grating 30. The thickness of the top layer 99 in the region of the emission regions 181, 182, 183 can be varied as desired.

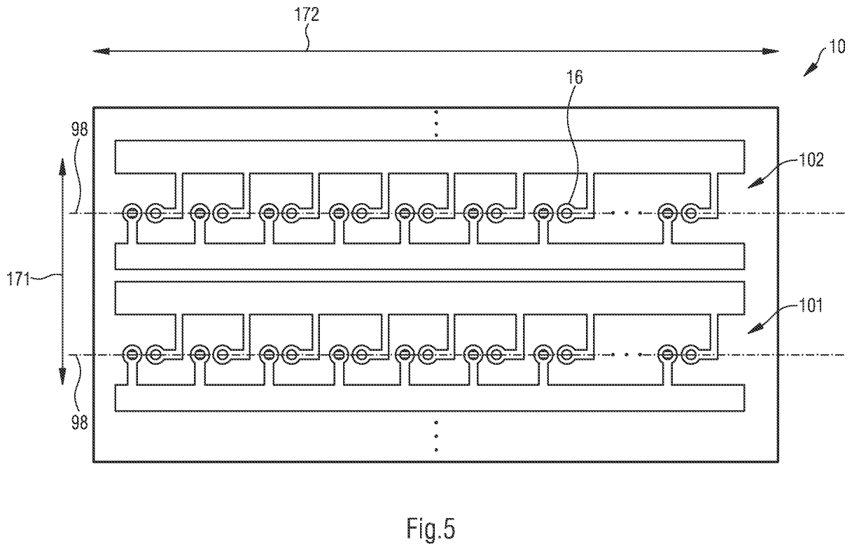

FIG. 5 shows a semiconductor component 10 which is in the form of an array. Said semiconductor component in the form of an array has at least two mesa rows 101, 102, which have mesa bodies 16 arranged next to one another in linear fashion. The adjacent mesa rows 101, 102 each extend along an imaginary line, wherein the imaginary lines are preferably parallel to one another.

By preference, the adjacent mesa rows have different absolute polarization extinction ratios with respect to to one another. For this purpose, the emission regions of the individual mesa bodies and the associated stress elements are designed in accordance with previous embodiments.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A semiconductor component for emitting light, the semiconductor component having a main body, the main body comprising:
at least one mesa body comprising:
an emission region for the light, the emission region comprising a first mirror portion, a second mirror portion, and an active portion arranged between the first mirror portion and the second mirror portion, the active portion serving to produce the light, and
an electrical contact for feeding electrical energy into the active portion, the electrical contact comprising at least one stress element extending up to the emission region, the stress element being attached to a surface of the main body and configured to generate, in the main body, a material stress, and
a polarization grating arranged on a surface of the mesa body and configured to interact with the emission region, wherein a grating alignment of the polarization grating includes an angle of 0°, 45° or 90° with respect to a direction of a predominant material stress or a longitudinal extent of the stress element, such that the material stress and the grating alignment have an effect on a property of the emitted light.

2. The semiconductor component as claimed in claim 1, wherein the property of the emitted light comprises a polarization extinction ratio.

3. The semiconductor component as claimed in claim 1, wherein the main body comprises at least two mesa bodies, each mesa body comprises a respective emission region and is assigned a respective stress element.

4. The semiconductor component as claimed in claim 3, wherein each respective emission region is assigned a respective polarization grating.

5. The semiconductor component as claimed in claim 4, wherein the polarization gratings for both emission regions have an identical grating alignment.

6. The semiconductor component as claimed in claim 4, wherein the polarization gratings for the two emission regions have respective grating alignments that are aligned orthogonally with respect to one another.

7. The semiconductor component as claimed in claim 3, wherein a top layer forming the surface of one mesa body is thinner in the respective emission region than a top layer forming the surface of the other mesa body in the respective emission region.

8. The semiconductor component as claimed in claim 1, wherein a longitudinal extent of the stress element includes an angle of 0°, 45° or 90° with respect to a crystal axis of the main body.

9. The semiconductor component as claimed in claim 1, wherein the at least one stress element comprises at least two separate stress elements attached to the main body, the two stress elements configured to generate predominant material stress in different directions.

10. The semiconductor component as claimed in claim 9, wherein the two different directions are at an angle of 0°, 45° or 90° with respect to one another.

11. The semiconductor component as claimed in claim 1, wherein the main body comprises a plurality of adjacent mesa rows, each mesa row having a plurality of mesa bodies arranged along an imaginary line.

12. The semiconductor component as claimed in claim 11, wherein the adjacent mesa rows have different polarization extinction ratios from one another.
